(19) United States
(12) Patent Application Publication
(10) Pub. No.: US 2019/0193199 A1
(43) Pub. Date: Jun. 27, 2019

(54) LASER PROCESSING APPARATUS

(71) Applicant: DISCO CORPORATION, Tokyo (JP)

(72) Inventor: Yuta YOSHIDA, Tokyo (JP)

(21) Appl. No.: 16/210,272

(22) Filed: Dec. 5, 2018

(30) Foreign Application Priority Data
Dec. 21, 2017 (JP) 2017-245017

(51) Int. Cl. B23K 26/06; B23K 26/066; H01L 21/67

(52) U.S. Cl. CPC B23K 26/0648; H01L 21/67092; B23K 26/0665; B23K 26/066

(57) ABSTRACT

A laser processing apparatus includes a laser oscillator oscillating a laser beam, a light condensing lens condensing the laser beam oscillated by the laser oscillator, and a mask member disposed between the laser oscillator and the light condensing lens and blocking part of the laser beam oscillated by the laser oscillator, in which the mask member includes a transmitting portion through which light passes, and a reflecting film surrounding the transmitting portion and reflecting the part of the laser beam.

### BACKGROUND OF THE INVENTION

### Field of the Invention

The present invention relates to a laser processing apparatus.

### Description of the Related Art

In recent years, device chips such as an integrated circuit (IC) chip, each incorporating a semiconductor device therein, have adopted a so-called low-dielectric insulating film (low-k film) with a low dielectric constant as an interlayer insulating film between wiring layers to be used for a device. When the low-k film is used for the interlayer insulating film, a parasitic capacitance formed between the wiring layers can be reduced, so that a throughput of the device chip can be enhanced. As the low-k film, a film of an inorganic material such as SiOF or SiOB (borosilicate glass) or a film of an organic material such as a polyimide-based and paraxylene-based polymer have been known. The device chip is formed by dividing a circular plate-shaped semiconductor wafer along a plurality of processing lines set so as to demarcate each device on a front surface of the wafer. Division of the wafer is performed by cutting the wafer along the processing lines with an annular-shaped cutting blade, for example. However, as the low-k film is extremely fragile, when the wafer having the low-k film laminated thereon is cut along the processing lines with the cutting blade, the low-k film peels off, and this peel-off reaches the device, thereby causing damage to the device.

To address this problem, there has been proposed a wafer dividing method in which a pulse-oscillated laser beam is irradiated to a wafer to remove a functional layer, thereby forming two streaks of processing grooves with a thickness deeper than a thickness of the functional layer on either side of the processing lines and cutting a region sandwiched by the two streaks of the processing grooves with a cutting blade (see Japanese Patent Laid-Open No. 2006-190779). However, even in a case where the functional layer is removed with a laser beam to form a processing groove in advance, irradiation of the laser beam peels off the functional layer from the wafer, causing degradation in quality of the device, in some cases. This peel-off occurs because a distribution of an energy density of the laser beam irradiated along the processing lines exhibits a Gaussian distribution. Particularly, skirt portions (bottom portions of a beam profile) of the distribution of the energy density serving as the Gaussian distribution cause the peel-off of the functional layer. To solve this problem, there has been proposed a laser processing apparatus including energy distribution modifying means modifying an energy distribution so as to cut off the skirt portions, and energy density adjusting means adjusting an energy density of a laser beam whose energy distribution is modified (see Japanese Patent Laid-Open No. 2010-158710).

### SUMMARY OF THE INVENTION

The energy distribution modifying means includes a mask member, for example. The mask member blocks the skirt portions to modify the energy distribution of the laser beam. Accordingly, in a case in which a laser oscillator with high output power is used, the mask member absorbs the laser beam to burn. As a result, damage to the mask member occurs. The present invention is achieved in view of such problem, and an object of the present invention is to provide a laser processing apparatus capable of preventing occurrence of damage due to blocking of the laser beam with the mask member which blocks part of the laser beam.

In accordance with an aspect of the present invention, there is provided a laser processing apparatus including a laser oscillator oscillating a laser beam, a light condensing lens condensing the laser beam oscillated by the laser oscillator, and a mask member disposed between the laser oscillator and the light condensing lens and blocking part of the laser beam oscillated by the laser oscillator, in which the mask member includes a transmitting portion through which light passes, and a reflecting film surrounding the transmitting portion and reflecting the part of the laser beam.

Preferably, the mask member may include a return preventing structure preventing the part of the laser beam from returning to the laser oscillator after the part of the laser beam is reflected by the reflecting film. The return preventing structure may include an irregular shape formed on a surface of the reflecting film reflecting the laser beam. In addition, the return preventing structure may include inclination of the reflecting film with respect to a plane orthogonal to a traveling direction of the laser beam passing through the transmitting portion.

The laser processing apparatus according to one mode of the present invention includes the mask member which blocks part of the laser beam oscillated by the laser oscillator, and the mask member includes the transmitting portion through which light passes, and the reflecting film surrounding the transmitting portion and reflecting the part of the laser beam. The reflecting film reflects part of the laser beam, so that the mask member blocks the part of the laser beam. Since the mask member does not absorb the blocked part of the laser beam, no damage to the mask member occurs. Accordingly, it is possible to provide a laser processing apparatus capable of preventing occurrence of damage due to blocking of the laser beam with the mask member which blocks part of laser beam.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically illustrating a laser processing apparatus;

FIG. 2 is a side elevational view of a laser processing unit;

FIG. 3 is a perspective view schematically illustrating a state in which laser processing of a workpiece is performed by the laser processing unit;

FIG. 4A is a perspective view schematically illustrating an example of a mask member;

FIG. 4B is a perspective view schematically illustrating another example of the mask member;

FIG. 5A is a cross-sectional view schematically illustrating an example of a mask member including a return preventing structure;

FIG. 5B is a cross-sectional view schematically illustrating another example of the mask member including the return preventing structure;

FIG. 6A is a cross-sectional view schematically illustrating still another example of the mask member including the return preventing structure; and

FIG. 6B is a cross-sectional view schematically illustrating yet another example of the mask member including the return preventing structure.

### DETAILED DESCRIPTION OF THE PREFERRED EMBODIMENT

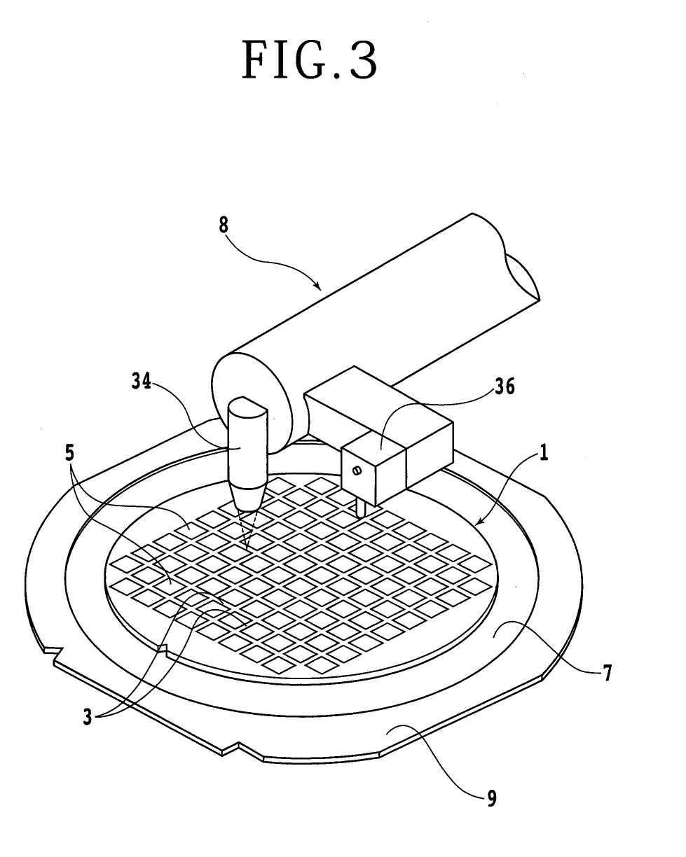

First, a workpiece of a laser processing apparatus according to the present embodiment will be described. FIG. 3 is a perspective view schematically illustrating a state in which laser processing of a workpiece 1 is performed. The workpiece 1 is a substrate including materials such as silicon, silicon carbide (SiC), or other semiconductors, or materials such as a sapphire, a glass, or a quartz, for example. The workpiece 1 may be a resin-molded substrate obtained by sealing a substrate in which devices are formed with a resin, or may be a layered substrate of a semiconductor wafer and a resin, for example. A front surface of the workpiece 1 is demarcated into a plurality of regions along a plurality of crossing processing lines (streets) 3, and each demarcated region has a device 5 such as an IC formed therein. As a final step, the workpiece 1 is divided along the processing lines 3 to form individual device chips.

The device 5 has a functional layer including a plurality of wiring layers and an interlayer insulating film which insulates between the wiring layers. In recent years, in order to reduce a parasitic capacitance formed between wiring layers, a so-called low-k film with a low dielectric constant has been used for an interlayer insulating film or the like. When the low-k film is used for the interlayer insulating film, a parasitic capacitance can be reduced, thereby enhancing a throughput of a device chip, or the like. Examples of the low-k film include a film of an inorganic material such as SiOF or SiOB (borosilicate glass) or a film of an organic material such as a polyimide-based and paraxylene-based polymer.

On a back surface of the workpiece 1, a tape 7 sticked to a frame 9 made of a metal is attached. The workpiece 1 is carried to the laser processing apparatus in a state of a frame unit having the tape 7 and the frame 9 integrated to the workpiece 1 and is processed. The tape 7 has a film-like base material with flexibility and a glue layer (adhesive layer) formed on one surface of the base material. For example, polyolefin (PO) is used for the base material. Alternatively, polyethylene terephthalate (PET), polyvinyl chloride, polystyrene, or the like, which have higher rigidity than PO, may be used for the base material. Also, as the glue layer (adhesive layer), a silicone rubber, an acrylic material, an epoxy-based material, or the like is used, for example.

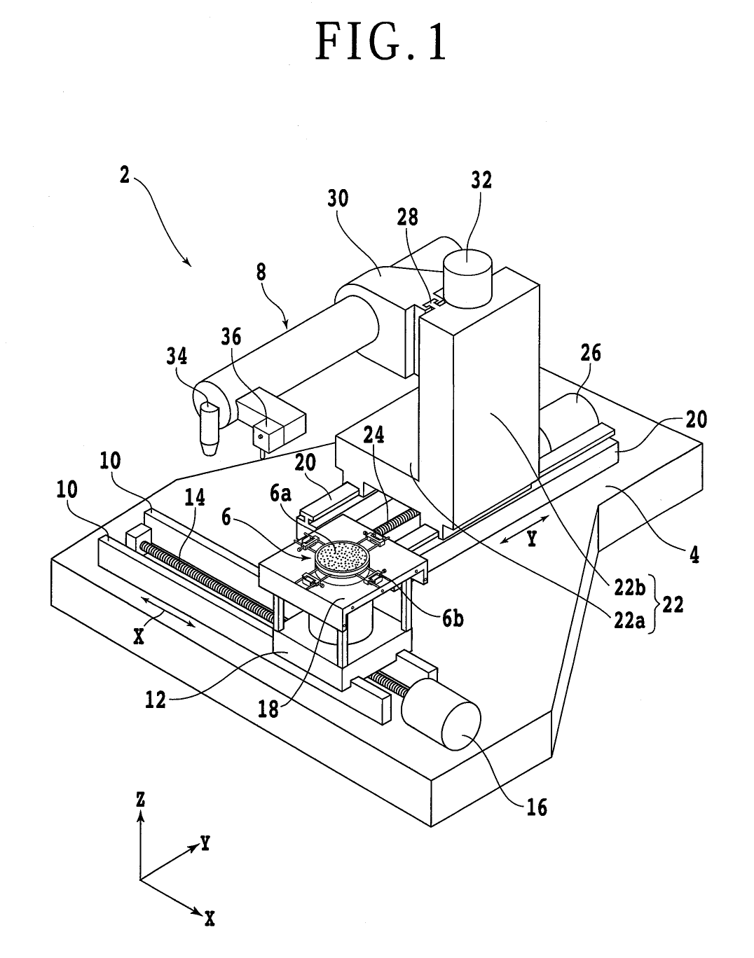

Next, a laser processing apparatus 2 according to the present embodiment will be described with reference to FIG. 1. The laser processing apparatus 2 includes a chuck table 6 holding and sucking the workpiece 1, and a laser processing unit 8 disposed above the chuck table 6. The laser processing apparatus 2 emits a pulse-oscillated laser beam to the workpiece 1 along the processing lines 3 on the workpiece 1 to remove the functional layer including the interlayer insulating film for which the low-k film is used, before dividing the workpiece 1.

A pair of X-axis guide rails 10 parallel to an X-axis direction is provided on a front portion of an upper surface of a base table 4 of the laser processing apparatus 2, and the X-axis guide rails 10 have an X-axis moving plate 12 slidably mounted thereon. The X-axis moving plate 12 has a nut (not illustrated) provided on a lower surface side thereof, and an X-axis ball screw 14 parallel to the X-axis guide rails 10 is screwed into the nut. An X-axis pulse motor 16 is coupled at one end of the X-axis ball screw 14.

On the X-axis moving plate 12, a support table 18 supporting the chuck table 6 is disposed, and the chuck table 6 is disposed on the support table 18. The chuck table 6 has a porous member (not illustrated) on an upper surface side thereof. An upper surface of the porous member functions as a holding surface 6a holding the workpiece 1. The chuck table 6 rotatably moves around an axis vertical to the holding surface 6a. The chuck table 6 has a suction source (not illustrated) connected with the porous member. When the workpiece 1 is mounted on the holding surface 6a and a negative pressure generated by the suction source is acted to the workpiece 1 through holes of the porous member, the workpiece 1 is held under suction on the chuck table 6. In addition, a plurality of cramps 6b fixing the frame 9 are provided around the chuck table 6.

When the X-axis ball screw 14 is rotated by the X-axis pulse motor 16, the X-axis moving plate 12 moves along the pair of X-axis guide rails 10 in the X-axis direction. The pair of X-axis guide rails 10, the X-axis moving plate 12, the X-axis ball screw 14, and the X-axis pulse motor 16 function as a processing-feeding unit processing-feeding the workpiece 1 held on the chuck table 6 in the X-axis direction. In other words, the X-axis direction serves as the processing feed direction.

A pair of Y-axis guide rails 20 along a Y-axis direction perpendicular to the X-axis direction is provided on a rear portion of the upper surface of the base table 4 of the laser processing apparatus 2. The Y-axis guide rails 20 have a supporting member 22 slidably mounted thereon. The supporting member 22 includes a base 22a mounted on the Y-axis guide rails 20, and a wall 22b erecting on the base 22a. The base 22a of the supporting member 22 has a nut (not illustrate) provided on a lower surface side thereof, and a Y-axis ball screw 24 parallel to the Y-axis guide rails 20 is screwed into the nut. A Y-axis pulse motor 26 is coupled at one end of the Y-axis ball screw 24. When the Y-axis ball screw 24 is rotated by the Y-axis pulse motor 26, the supporting member 22 moves along the pair of Y-axis guide rails 20 in the Y-axis direction. The pair of Y-axis guide rails 20, the Y-axis ball screw 24, and the Y-axis pulse motor 26 function as an index-feeding unit indexing-feeding the laser processing unit 8 to be described later in the Y-axis direction. In other words, the Y-axis direction serves as an indexing feed direction.

On a rear surface side of the wall 22b of the supporting member 22, a pair of Z-axis guide rails 28 along a Z-axis direction vertical to the X-axis direction and the Y-axis direction is disposed. The Z-axis guide rails 28 has a unit holder 30 slidably mounted thereon. A nut (not illustrated) is provided on a surface of the unit holder 30 facing the wall 22b, and a Z-axis ball screw (not illustrated) parallel to the pair of Z-axis guide rails 28 is screwed into the nut. A Z-axis pulse motor 32 is coupled at one end of the Z-axis ball screw. When the Z-axis ball screw is rotated by the Z-axis pulse motor 32, the unit holder 30 moves along the pair of Z-axis guide rails 28 in the Z-axis direction. The pair of Z-axis guide rails 28, the Z-axis ball screw, and the Z-axis pulse motor 32 function as an elevating unit elevating the laser processing unit 8 in the Z-axis direction.

The unit holder 30 has the laser processing unit 8 fixed thereto. The laser processing unit 8 has a function of processing the workpiece 1 by emitting a pulse-oscillated laser beam to the workpiece 1 held on the holding surface 6a of the chuck table 6. The laser processing unit 8 includes a processing head 34 positioned above the chuck table 6, and an imaging unit 36 adjacent to the processing head 34. The imaging unit 36 images the front surface of the workpiece 1 held on the chuck table 6 and is used in performing alignment such that the workpiece 1 is irradiated with the laser beam along the processing lines 3.

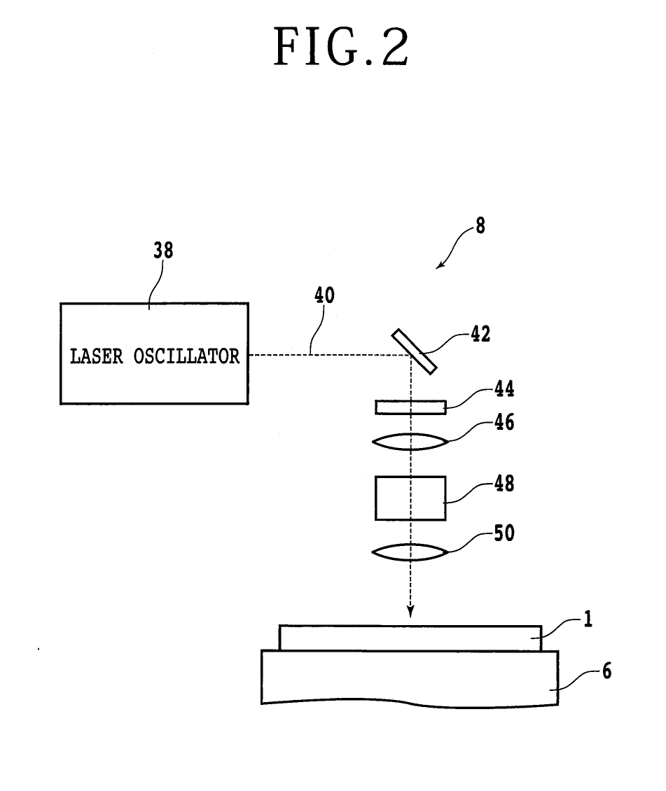

A configuration of the laser processing unit 8 will be described with reference to FIG. 2. FIG. 2 is a side elevational view schematically illustrating the configuration of the laser processing unit 8. As illustrated in FIG. 2, the laser processing unit 8 includes a laser oscillator 38 oscillating a laser beam 40, a mirror 42, a relay lens 46, a cylindrical lens 48, and a light condensing lens 50. The laser processing unit 8 includes a mask member 44 in an optical path of the laser beam 40 between the laser oscillator 38 and the light condensing lens 50. The laser oscillator 38 has a function of oscillating the laser beam 40 with such a wavelength as to be absorbed in the workpiece 1. For example, a laser beam with a wavelength of 355 nm which is oscillated through Nd:YAG or the like as a medium. In laser processing of the workpiece 1, for example, the laser beam 40 is oscillated under a condition of a pulse width of 40 ns or less, a frequency of 100 kHz, and an output power of 20 W or less. Upon processing, the laser beam 40 is irradiated to the workpiece 1 under a condition in which a feed speed of processing the workpiece 1 is 700 to 1000 mm/s and the number of times of irradiation for each of the processing lines is three to four times.

The laser beam 40 oscillated by the laser oscillator 38 is reflected by the mirror 42 in a predetermined direction and passes through the relay lens 46 and the light condensing lens 50 to be applied to the workpiece 1 held on the chuck table 6. The cylindrical lens 48 disposed between the relay lens 46 and the light condensing lens 50 has, for example, a function of deforming the laser beam 40 into a laser beam of an elliptical shape having a longitudinal axis in a direction orthogonal to the processing feed direction of the workpiece 1.

When the laser beam 40 is applied to the workpiece 1 to form a processing groove and the functional layer including the low-k film is removed, peel-off of the functional layer from the workpiece 1 may occur, causing degradation in quality of a device chip obtained from the workpiece 1, in some cases. This peel-off occurs because an energy density of the laser beam 40 applied to the workpiece 1 along the processing lines 3 exhibits a Gaussian distribution. Particularly, skirt portions of the distribution of the energy density serving as the Gaussian distribution cause the peel-off of the functional layer.

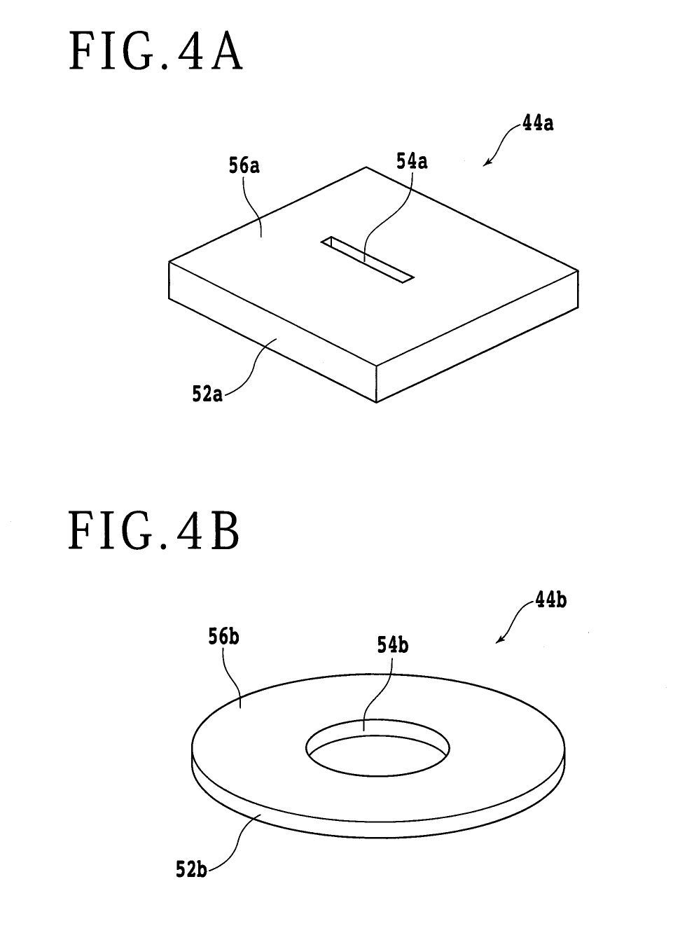

The mask member 44 functions as energy distribution modifying means modifying the energy distribution so as to cut off the skirt portions. FIG. 4A is a perspective view illustrating one example of the mask member 44. A mask member 44a illustrated in FIG. 4A includes a base material 52a formed of materials such as stainless steel, a ceramic glass, or a quartz, and a transmitting portion 54a (through hole) penetrating through the base material 52a. A shape of the transmitting portion 54a is set to be a rectangular shape having a long side in a direction along the longitudinal axis of the laser beam 40 which is deformed into an elliptical shape by the cylindrical lens 48, for example. When the laser beam 40 is made to pass through the transmitting portion 54a of the mask member 44a, part corresponding to the skirt portions of the distribution of the energy density of the laser beam 40 is blocked, and accordingly, the distribution of the energy density is modified.

A reflecting film 56a surrounding the transmitting portion 54a is formed over an upper surface of the mask member 44a. In a case in which the reflecting film 56a is not formed over the upper surface of the mask member 44a, with high output of the laser beam 40, the base material 52a of the mask member 44a absorbs the part of the laser beam 40 corresponding to the skirt portions described above, thereby causing damage to the base material 52a in some cases. In contrast, the laser processing apparatus 2 according to one mode of the present embodiment includes the reflecting film 56a over the upper surface of the mask member 44a, the part of the laser beam 40 corresponding to the skirt portions described above are reflected by the reflecting film 56a, so that the part of the laser beam 40 does not reach the base material 52a, thereby causing no damage to the base material 52a. However, when the part of the laser beam 40 reflected by the reflecting film 56a travels back in a reverse direction and reaches the laser oscillator 38, this return light may damage the laser oscillator 38 or may destabilize operation of the laser oscillator 38. To prevent such adverse behaviors, the mask member 44a may preferably include a return preventing structure preventing the part of the laser beam 40 reflected by the reflecting film 56a from going back to the laser oscillator 38 in the laser processing apparatus 2 according to the present embodiment. The return preventing structure will be described below.

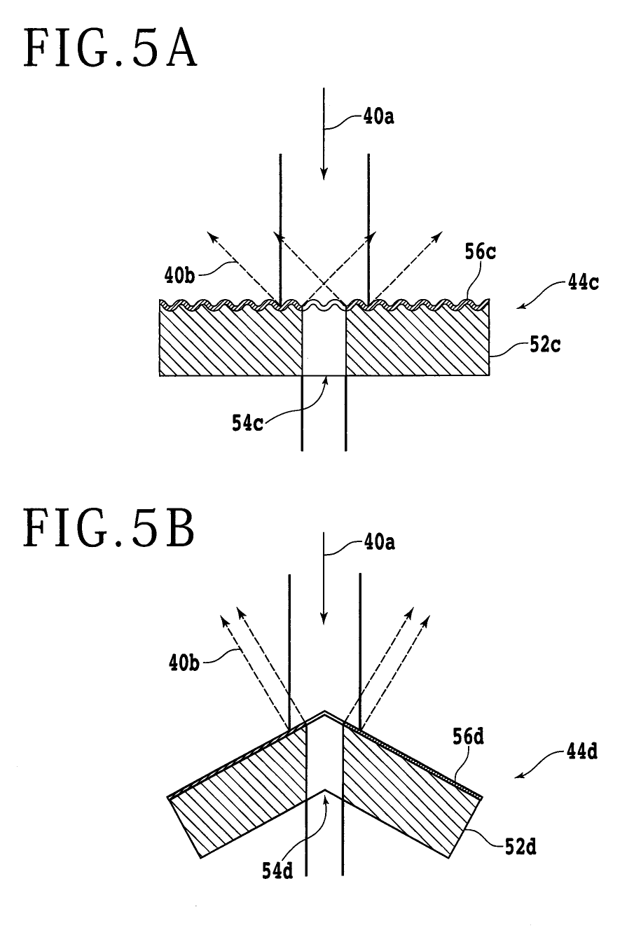

FIG. 5A is a cross-sectional view schematically illustrating an example of a mask member 44c including the return preventing structure. Regarding the mask member 44c, a surface of a reflecting film 56c reflecting part of the laser beam 40a has an irregular shape. The reflecting film 56c is, for example, formed by depositing a metal or the like on an upper surface of a base material 52c having an irregular shape. The part of the laser beam 40a which is oscillated by the laser oscillator 38 and then reaches the mask member 44c is reflected by the reflecting film 56c. However, since the upper surface of the reflecting film 56c is an irregular shape, reflected laser beams 40b are scattered. Accordingly, the reflected laser beams 40b neither return to the laser oscillator 38 to damage the laser oscillator 38 nor destabilize the operation of the laser oscillator 38. More specifically, the irregular shape of the upper surface of the reflecting film 46c functions as the return preventing structure. Then, the laser beam 40a passes through the transmitting portion 54c, and an energy distribution of the laser beam 40a is then modified. The laser beam 40a is thus irradiated to the workpiece 1.

Another example of the mask member will be described with reference to FIG. 5B. FIG. 5B is a cross-sectional view schematically illustrating another example of the mask member including the return preventing structure. Regarding a mask member 44d illustrated in FIG. 5B, a reflecting film 56d is inclined with respect to a plane orthogonal to a traveling direction of the laser beam 40a passing through a transmitting portion 54d. For example, the reflecting film 56d has one side and the other side inclined to each other in an opposite direction. Accordingly, the part of the laser beam 40a oscillated by the laser oscillator 38 and then reaching the mask member 44d is reflected in a direction other than the traveling direction of the laser beam 40a. Thus, the laser beams 40b reflected by the reflecting film 56d may not return to the laser oscillator 38 to have an adverse effect on the laser oscillator 38. More specifically, in the mask member 44d, the inclination of the reflecting film 56d functions as the return preventing structure. Note that, when the mask member 44d is used, the reflected laser beams 40b each travel in a specific direction. Accordingly, it may be possible to provide a member absorbing or scattering the laser beams 40b inside the laser processing unit 8 in the traveling direction of the laser beams 40b.

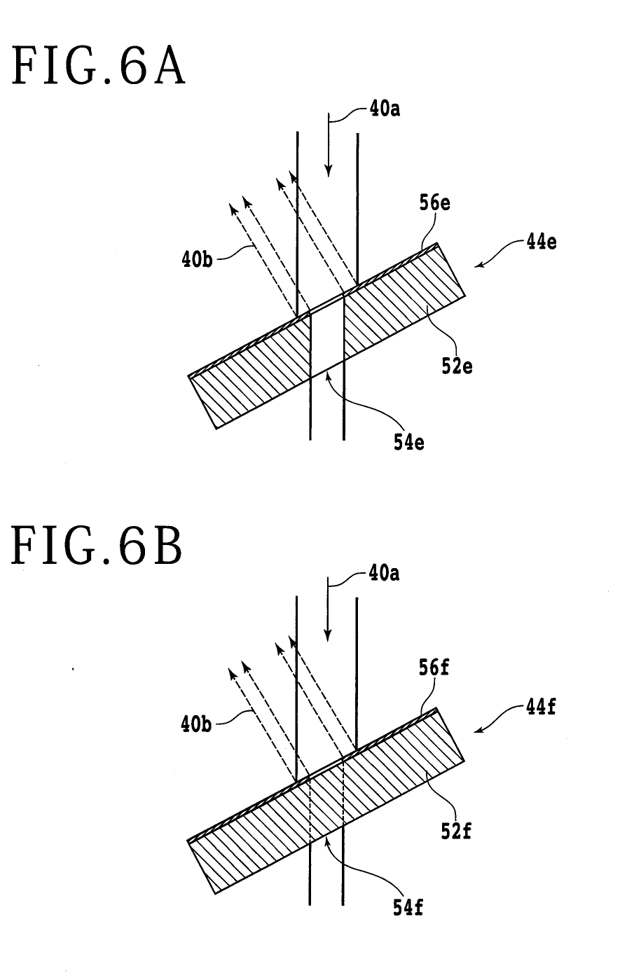

Moreover, another example of the mask member will be described with reference to FIG. 6A. FIG. 6A is a cross-sectional view schematically illustrating still another example of the mask member including the return preventing structure. A mask member 44e illustrated in FIG. 6A has a through hole penetrating along a direction inclined from a thickness direction of a base material 52e provided as a transmitting portion 54e. The mask member 44e is disposed inside the laser processing unit 8 in such a way that a direction of the mask member 44e is adjusted such that a penetrating direction of the through hole corresponds to the traveling direction of the laser beam 40a. Accordingly, also in the mask member 44e, a reflecting film 56e is inclined with respect to a plane orthogonal to the traveling direction of the laser beam 40a passing through the transmitting portion 54e. This inclination of the reflecting film 56e functions as the return preventing structure. In this case, since the laser beam 40b reflected by the reflecting film 56e travels in one direction, it is sufficient to provide one member for absorbing or scattering the reflected laser beam 40b in the traveling direction of the reflected laser beam 40b.

In addition, regarding yet another example of the mask member will be described with reference to FIG. 6B. FIG. 6B is a cross-sectional view schematically illustrating yet another example of the mask member including the return preventing structure. A base material 52f of a mask member 44f illustrated in FIG. 6B is formed of a member transmitting light of a wavelength of the laser beam 40a. An opening is formed in a reflecting film 56f formed over the base material 52f. When the laser beam 40a is made to travel toward the mask member 44f, part of the laser beam 40a is reflected by the reflecting film 56f, part other than the reflected part of the laser beam 40a travels in the opening to pass through the base material 52f. Accordingly, the opening defines a transmitting portion 54f of the mask member 44f. In the mask member 44f, an inclination angle of the reflecting film 56f with respect to a plane orthogonal to the traveling direction of the laser beam 40a can be set to an arbitrary angle. Thus, by changing the inclination angle, a width of the transmitting portion 54f in a direction orthogonal to the traveling direction of the laser beam 40a can be changed, and the width can be set depending on the distribution of the energy density of the laser beam 40a.

As described above, in the laser processing apparatus 2 according to the present embodiment, the part of the laser beam 40 oscillated from the laser oscillator 38 is reflected by the reflecting film of the mask member 44. Since the mask member 44 does not absorb the part of the laser beam 40, no damage to the mask member 44 occurs. Accordingly, a laser processing apparatus capable of preventing occurrence of damage due to blocking of the laser beam 40 with the mask member 44 blocking part of the laser beam 40 is provided. Also, in a case in which the mask member 44 includes a return preventing structure, the laser beam reflected by the reflecting film of the mask member 44 does not return to the laser oscillator 38. Thus, it is possible to prevent occurrence of damage to the laser oscillator 38 or destabilization of operation of the laser oscillator 38.

Laser processing of the workpiece 1 by the laser processing unit 8 including the mask member 44 having the reflecting film disposed thereon will be next described. First, the workpiece 1 is carried on the holding surface 6a of the chuck table 6 via the tape 7, with the cramps 6b gripping the frame 9, and a negative pressure is made to act on the workpiece 1, so that the workpiece 1 is held on the chuck table 6. Next, the front surface of the workpiece 1 is imaged by the imaging unit 36, and the processing-feeding unit and the index-feeding unit are controlled to locate the workpiece 1 and the processing head 34 at a predetermined position such that the workpiece 1 can be laser-processed along the processing lines 3. FIG. 3 is a perspective view schematically illustrating a state in which laser processing of the workpiece 1 is performed. Next, by causing the laser oscillator 38 to pulse-oscillate the laser beam 40 and then apply the oscillated laser beam 40 to the workpiece 1, the workpiece 1 is laser-processed along the processing lines 3, thereby removing the functional layer. Since the irradiated laser beam 40 passes through the mask member 44, the distribution of the energy density is modified by the mask member 44, and accordingly, the skirt portions of the distribution are cut off. Thus, even if the workpiece 1 is laser-processed, the functional layer does not peel off, and then, the device chips obtained after the workpiece 1 is divided do not reduce in quality.

Note that the present invention is not limited to descriptions of the above-described embodiment, and can be implemented in various modifications. For example, in the embodiment described above, a description has been given regarding a mask member 44a including the transmitting portion 54a having a rectangular planar shape; however, one mode of the present invention is not limited to this. For example, in the laser processing apparatus 2 according to one mode of the present invention, the mask member 44 may include a transmitting portion having a circular planar shape. FIG. 4B is a perspective view schematically illustrating another example of the mask member. As illustrated in FIG. 4B, the laser processing apparatus 2 may include a mask member 44b including a transmitting portion 54b having a circular planar shape. In the mask member 44b, a circular through hole is formed in a base material 52b and a reflecting film 56b layered over the base material 52b, and the through hole functions as the transmitting portion 54b. Moreover, the mask member 44b may include the return preventing structure preventing the laser beam 40 reflected by the reflecting film 56b from returning to the laser oscillator 38.

Alternatively, the mask member 44 may be disposed in an optical path between the cylindrical lens 48 and the light condensing lens 50, for example. In this case, the laser beam deformed into an elliptical shape by the cylindrical lens 48 travels into the mask member 44, and accordingly, the distribution of the energy density is modified. Hence, a shape of the transmitting portion and a shape of the opening of the reflecting film are set to be a shape capable of modifying the distribution of the energy density of the laser beam deformed by the cylindrical lens 48.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A laser processing apparatus comprising:
a laser oscillator oscillating a laser beam;
a light condensing lens condensing the laser beam oscillated by the laser oscillator; and
a mask member disposed between the laser oscillator and the light condensing lens and blocking part of the laser beam oscillated by the laser oscillator,
wherein the mask member includes a transmitting portion through which light passes, and a reflecting film surrounding the transmitting portion and reflecting the part of the laser beam.

2. The laser processing apparatus according to claim 1,
wherein the mask member includes a return preventing structure preventing the part of the laser beam from returning to the laser oscillator after the part of the laser beam is reflected by the reflecting film.

3. The laser processing apparatus according to claim 2,
wherein the return preventing structure includes an irregular shape formed on a surface of the reflecting film reflecting the laser beam.

4. The laser processing apparatus according to claim 2,
wherein the return preventing structure includes inclination of the reflecting film with respect to a plane orthogonal to a traveling direction of the laser beam passing through the transmitting portion.
